(19) United States
(12) Patent Application Publication
(10) Pub. No.: US 2026/0049231 A1
(43) Pub. Date: Feb. 19, 2026

(54) POLISHING AGENT, POLISHING METHOD, METHOD FOR MANUFACTURING SEMICONDUCTOR COMPONENT, AND ADDITIVE SOLUTION FOR POLISHING AGENT

(71) Applicant: AGC INC., Tokyo (JP)

(72) Inventor: Yasuhisa NOZAWA, Tokyo (JP)

(73) Assignee: AGC INC., Tokyo (JP)

(21) Appl. No.: 19/367,976

(22) Filed: Oct. 24, 2025

Related U.S. Application Data
(63) Continuation of application No. PCT/JP2024/014312, filed on Apr. 8, 2024.

(30) Foreign Application Priority Data
Apr. 28, 2023 (JP) 2023-074452

(51) Int. Cl. C09G 1/02; B24B 37/04; H01L 21/306; H01L 21/78

(52) U.S. Cl. CPC C09G 1/02; B24B 37/044; H01L 21/30625; H01L 21/78

(57) ABSTRACT

A polishing agent which has excellent storage stability and a high selective ratio between a silicon oxide and a stopper film while maintaining the silicon oxide removal. A polishing agent containing abrasive grains, an anionic polymer, an acidic compound selected from phosphoric acid compounds and organic acid compounds, and water, wherein the anionic polymer is a copolymer containing a hydrophobic monomer and an anionic monomer, an acid value of the anionic polymer is 20 to 400 mgKOH/g; a partition coefficient of the hydrophobic monomer is 0 to 4; the anionic monomer contains at least one type selected from unsaturated monocarboxylic acids and salts thereof, and when an acid compound having a highest molar concentration among the acidic compounds is defined as a first acidic compound, pKa of the first acidic compound and pH of the polishing agent satisfy a following relationship: |pKa−pH|≤1.5.

### INCORPORATION BY REFERENCE

This application is based upon and claims the benefit of priority from Japanese patent application No. 2023-74452, filed on Apr. 28, 2023, and PCT application No. PCT/JP2024/014312 filed on Apr. 8, 2024, the disclosure of which is incorporated herein in its entirety by reference.

### BACKGROUND

The present disclosure relates to a polishing agent, a polishing method, a method for manufacturing a semiconductor component, and an additive solution for a polishing agent.

As packing densities of semiconductor integrated circuits increase and their functions become more sophisticated, the development of microfabrication technology for making structures of semiconductor elements finer and more densified has been progressing. In the manufacturing of semiconductor integrated circuit devices (hereinafter also referred to as a semiconductor devices), conventionally, interlayer insulating films, buried wiring lines, and the like are flattened by using Chemical Mechanical Polishing (hereinafter referred to as CMP) in order to prevent a problem that irregularities (differences in level) on the surface of a layer exceed the focal depth of lithography and hence a sufficient resolution cannot be obtained. As the demand for making elements more precise and finer is increasing, the importance of high flatness obtained by CMP is increasing more and more.

Further, in the manufacture of semiconductor devices, shallow trench isolation (STI: Shallow Trench Isolation) in which an element isolation width is small has been introduced in order to make semiconductor devices finer even further.

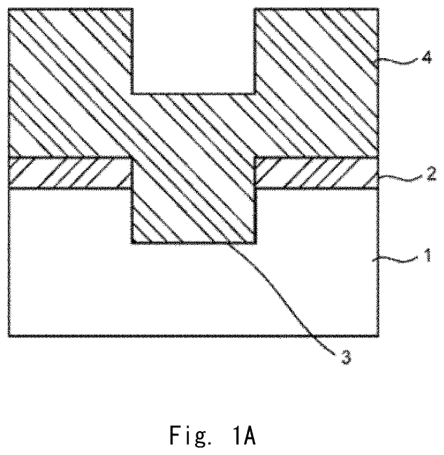

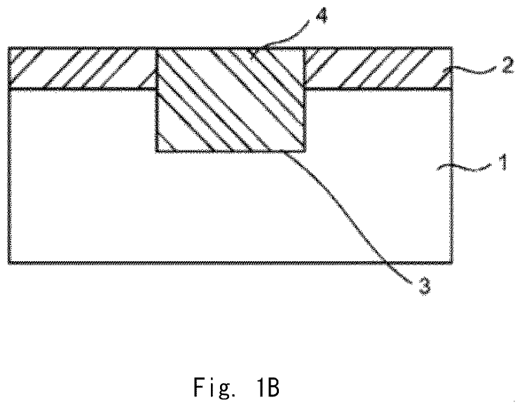

STI is a method for forming an electrically insulated element region by forming a trench (groove) in a silicon substrate and embedding an insulating film in the trench. An example of STI will be described with reference to FIGS. 1A and 1B. In this example, first, as shown in FIG. 1A, an element region on a silicon substrate 1 is masked with a stopper film 2. Then, a trench 3 is formed in the silicon substrate 1, and an insulating film such as a silicon oxide film 4 is deposited so as to fill the trench 3 therewith. Next, by CMP, while leaving the part of the silicon oxide film 4 located inside the trench 3, which is a recessed part, the remaining part of the silicon oxide film 4 located over the stopper film 2, which is a protruding part(s), is polished and thereby removed. By doing so, an element isolation structure in which the silicon oxide film 4 is embedded in the trench 3 is obtained as shown in FIG. 1B.

In CMP in STI, by increasing the selective ratio (removal rate ratio) between the silicon oxide film and the stopper film, it is possible to stop the progress of the polishing at the point when the stopper film is exposed. Examples of such stopper films include a nitride film and a polysilicon film. In the polishing method using a stopper film, it is possible to obtain a surface smoother than those obtained in other ordinary polishing methods. Further, in the recent CMP technology, there is a demand for increasing the above-described selective ratio.

For example, Patent Literature 1 discloses, as a method for increasing such a selective ratio between a silicon dioxide film and a silicon nitride film, a polishing agent containing a specific water-soluble polymer, cerium oxide particles, and water, and having pH of 4 to 9.
Patent Literature 1: Japanese Unexamined Patent Application Publication No. 2019-87660

### SUMMARY

In view of the above-described problem, an object of the present disclosure is to provide a polishing agent which has excellent storage stability and with which it is possible to obtain a high selective ratio between a silicon oxide film and a stopper film while maintaining the removal rate of the silicon oxide film, and an additive solution for a polishing agent for preparing such a polishing agent, and also to provide a polishing method capable of performing high-speed polishing and a method for manufacturing a semiconductor component using the polishing method.

The present disclosure provides a polishing agent, an additive solution for a polishing agent, a polishing method, and a method for manufacturing a semiconductor component having the following features.
[1] A polishing agent containing abrasive grains, an anionic polymer, an acidic compound selected from phosphoric acid compounds and organic acid compounds, and water, wherein
   the anionic polymer is a copolymer containing a hydrophobic monomer and an anionic monomer,
   an acid value of the anionic polymer is 20 mgKOH/g to 400 mgKOH/g,
   a partition coefficient (log D) of the hydrophobic monomer is 0 to 4,
   the anionic monomer contains at least one type selected from unsaturated monocarboxylic acids and salts thereof, and
   when an acid compound having a highest molar concentration among the acidic compounds is defined as a first acidic compound, pKa of the first acidic compound and pH of the polishing agent satisfy a relationship expressed by below-shown Formula (1)

|pKa−pH|≤1.5 (1)
where when the first acidic compound has two or more acid dissociation constants, pKa represents an acid dissociation constant closest to pH.
[2] The polishing agent described in Item [1], wherein the abrasive grains include at least one type selected from the group consisting of silica particles, alumina particles, zirconia particles, cerium compound particles, titania particles, germania particles, composite particles thereof, and core shell-type particles.
[3] The polishing agent described in Item [1] or [2], wherein the abrasive grains include cerium compound particles.
[4] The polishing agent described in any one of Items [1] to [3], wherein the abrasive grains include ceria particles.
[5] The polishing agent described in any one of Items [1] to [4], wherein a content of the abrasive grains is 0.01 to 10.0 wt. % based on a total weight of the polishing agent.
[6] The polishing agent described in any one of Items [1] to [5], wherein an acid value of the anionic polymer is 20 mgKOH/g to 300 mgKOH/g.
[7] The polishing agent described in any one of Items [1] to [6], wherein a partition coefficient (log D) of the hydrophobic monomer is 0 to 3.
[8] The polishing agent described in any one of Items [1] to [7], wherein the hydrophobic monomer contains alkyl (meth)acrylate.
[9] The polishing agent described in any one of Items [1] to [8], wherein a weight-average molecular weight of the anionic polymer is 1,000 to 100,000.
[10] The polishing agent described in any one of Items [1] to [9], wherein a ratio of the hydrophobic monomer in the anionic polymer is 10 to 95 mol % based on whole monomers constituting the anionic polymer.
[11] The polishing agent described in any one of Items [1] to [10], wherein a content of the anionic polymer is 0.02 wt. % to 0.5 wt. % based on a total weight of the polishing agent.
[12] The polishing agent described in any one of Items [1] to [11], wherein the pKa is 4 to 9.
[13] The polishing agent described in any one of Items [1] to [12], further containing a nonionic polymer.
[14] The polishing agent described in any one of Items [1] to [13], wherein pH is 4 to 9.
[15] A polishing method in which a polishing pad is brought into contact with a surface to be polished of a semiconductor substrate while supplying a polishing agent therebetween, and the surface to be polished is polished by relative motion of the surface to be polished and the polishing pad, wherein the polishing agent is a polishing agent described in any one of Items [1] to [14].
[16] A method for manufacturing a semiconductor component, wherein the semiconductor component is obtained by dividing a semiconductor substrate having a surface to be polished, polished by the polishing method described in Item [15] into pieces.
[17] An additive solution for a polishing agent containing an anionic polymer, an acidic compound selected from phosphoric acid compounds and organic acid compounds, and water, wherein
   the anionic polymer is a copolymer containing a hydrophobic monomer and an anionic monomer,
   an acid value of the anionic polymer is 20 mgKOH/g to 400 mgKOH/g,
   a partition coefficient (log D) of the hydrophobic monomer is 0 to 4,
   the anionic monomer contains at least one type selected from unsaturated monocarboxylic acids and salts thereof, and
   when an acid compound having a highest molar concentration among the acidic compounds is defined as a first acidic compound, pKa of the first acidic compound and pH of the additive solution for the polishing agent satisfy a relationship expressed by below-shown Formula (1)

$$\vert pKa - pH \vert \leq 1.5 \qquad ( 1 )$$

where when the first acidic compound has two or more acid dissociation constants, pKa represents an acid dissociation constant closest to pH.

According to the present disclosure, it is possible to provide a polishing agent which has excellent storage stability and with which it is possible to obtain a high selective ratio between a silicon oxide film and a stopper film while maintaining the removal rate of the silicon oxide film, and an additive solution for a polishing agent for preparing such a polishing agent, and also to provide a polishing method capable of performing high-speed polishing and a method for manufacturing a semiconductor component using the polishing method.

The above and other objects, features and advantages of the present disclosure will become more fully understood from the detailed description given hereinbelow and the accompanying drawings.

### DESCRIPTION OF EMBODIMENTS

FIG. 1A shows an example of a polishing method, and is a cross-sectional diagram showing a state of an object to be polished before being polished;

FIG. 1B shows the example of the polishing method, and is a cross-sectional diagram showing a state of the object to be polished after being polished; and

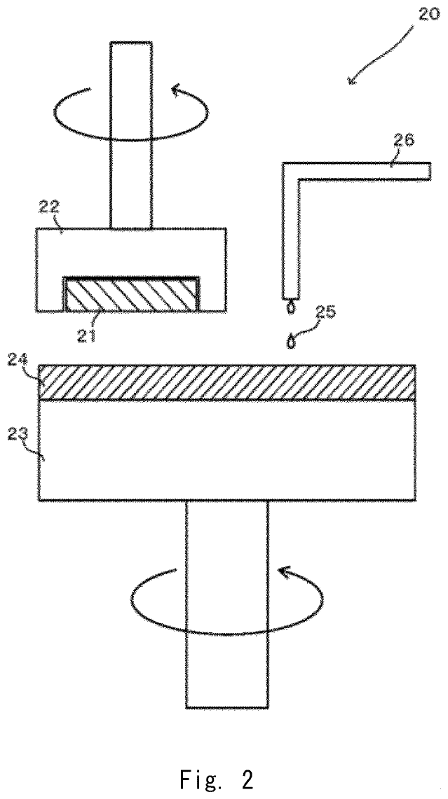

FIG. 2 is a schematic diagram showing an example of a polishing apparatus.

### DETAILED DESCRIPTION

Embodiments according to the present invention will be described hereinafter. The present invention is not limited to the below-shown embodiments, and other embodiments may also fall within the scope of the present invention as long as they are consistent with the purport of the present invention. For clarifying the explanation, the following description and drawings are simplified as appropriate. Further, for the sake of explanation, the scales of members in the drawings may widely differ from one another.

Note that in the present disclosure, the term “surface to be polished” means a surface to be polished of an object to be polished, for example, a front surface thereof. In the specification of the present application, surfaces at intermediate stages, i.e., surfaces that appear in semiconductor substrates during a process for manufacturing a semiconductor device, are also included in the “surface to be polished”.

The “silicon oxide” is mainly silicon dioxide, but it is not limited to silicon dioxide and includes silicon oxides other than silicon dioxide.

The “selective ratio” means a ratio (R_{A}/R_{B}) of a removal rate (R_{A}) of an object to be polished A (e.g., a silicon oxide film) to a removal rate (R_{B}) of a stopper film B (e.g., a silicon nitride film).

“(meth)acryl” is a general term for “methacryl” and “acryl”, and the same applies to (meth)acryloyl, (meth)acrylate, and the like.

Further, unless otherwise specified, when a symbol “−” (or “to”), which indicates a numerical range, is used, it means that a numerical value in front of the symbol and that behind the symbol are included as a lower limit value and an upper limit value, respectively, in the range.

### [Polishing Agent]

The polishing agent according to the present disclosure (hereinafter, also referred to as the polishing agent disclosed herein) is a polishing agent containing abrasive grains, an anionic polymer, an acidic compound selected from phosphoric acid compounds and organic acid compounds, and water, in which
the anionic polymer is a copolymer containing a hydrophobic monomer and an anionic monomer,
an acid value of the anionic polymer is 20 mgKOH/g to 400 mgKOH/g,
a partition coefficient (log D) of the hydrophobic monomer is 0 to 4,
the anionic monomer contains at least one type selected from unsaturated monocarboxylic acids and salts thereof, and
when an acid compound having a highest molar concentration among the acidic compounds is defined as a first acidic compound, pKa of the first acidic compound and pH of the polishing agent satisfy a relationship expressed by below-shown Formula (1)

$$\vert pKa - pH \vert \leq 1.5 \qquad ( 1 )$$

where when the first acidic compound has two or more acid dissociation constants, pKa represents an acid dissociation constant closest to pH.

For example, by using the polishing agent disclosed herein in CMP of a surface to be polished including a silicon oxide film in STI, it is possible to suppress the polishing of the stopper film while maintaining a high removal rate for the silicon oxide film, and thereby to obtain a high selective ratio between the silicon oxide film and the stopper film, thus making it possible to carry out polishing with high flatness. Further, the polishing agent disclosed herein has excellent storage stability, so that changes in pH and viscosity are suppressed even when the polishing agent is stored for a long time.

Note that examples of materials for the stopper film include: compounds containing one or more types selected from silicon, carbon, hafnium, zirconium, cobalt, ruthenium, molybdenum, titanium, tantalum, and copper; and nitrides containing one or more of them, and oxides containing one or more of them. More specifically, examples include: a metal itself such as copper, cobalt, ruthenium, molybdenum, titanium, and tantalum; a nitride such as titanium nitride, tantalum nitride, and silicon nitride; an oxide such as zirconia and hafnium oxide; polysilicon, amorphous silicon, hafnium silicate, zirconium silicate, silicon carbide, and the like. Among them, silicon nitride or polysilicon is preferred in order to obtain a higher selective ratio.

The polishing agent disclosed herein contains at least abrasive grains, an anionic polymer, an acidic compound, and water, and may further contain other components as long as the effects of the embodiment are achieved. Each of the components contained in the polishing agent disclosed herein will be described hereinafter.

### <Abrasive Grains>

In the polishing agent disclosed herein, the abrasive grains may be selected as appropriate from among those used as abrasive grains for CMP. Examples of abrasive grains include at least one type selected from the group consisting of silica particles, alumina particles, zirconia particles, cerium compound particles (e.g., ceria particles, cerium hydroxide particles), titania particles, germania particles, and core shell-type particles using these particles as core particles. Examples of the silica particles include colloidal silica and fumed silica. Colloidal alumina may also be used as the alumina particles.

The core shell-type particles consist of core particles (e.g., silica particles, alumina particles, zirconia particles, cerium compound particles, titania particles, or germania particles) and thin films covering the surfaces of the core particles.

Examples of the material of the thin film include at least one type selected from oxides such as silica, alumina, zirconia, ceria, titania, germania, iron oxide, manganese oxide, zinc oxide, yttrium oxide, calcium oxide, magnesium oxide, lanthanum oxide, and strontium oxide. Further, the thin film may be formed from a plurality of nanoparticles consisting of these oxides.

The particle size of the aforementioned core particles is preferably 0.01 μm to 0.5 μm and more preferably 0.03 μm to 0.3 μm.

It is sufficient if the particle size of the aforementioned nanoparticles is smaller than the particle size of the aforementioned core particles, and the particle size of the nanoparticles preferably 1 nm to 100 nm and more preferably 5 nm to 80 nm.

Among the above-mentioned abrasive grains, silica particles, alumina particles, or cerium compound particles are preferred in view of the excellent removal rate of the insulating film. Further, cerium compound particles are more preferred, and ceria particles are still more preferred because a high removal rate can be obtained when the surface to be polished includes an insulating film (in particular, a silicon oxide film). In the case of core shell-type particles, the thin film preferably contains silica, alumina, or a cerium compound. More preferably, the thin film contains ceria. Only one type of abrasive grains may be used, or two or more types of abrasive grains may be used in combination.

The content of ceria based on the total weight of abrasive grains is preferably 70 wt. % or more, more preferably 80 wt. % or more, still more preferably 90 wt. % or more, particularly preferably 95 wt. % or more, and most preferably 100 wt. %. When the content of ceria based on the total weight of abrasive grains is 70 wt. % or more, it is easy to improve, in particular, the removal rate of the insulating film.

Ceria particles may be selected as appropriate from known ones and used. Examples of know ceria particles include ceria particles manufactured by methods disclosed in Japanese Unexamined Patent Application Publication No. H11-12561, Japanese Unexamined Patent Application Publication No. 2001-35818, and Published Japanese Translation of PCT International Publication for Patent Application, No. 2010-505735. Specifically, examples of them include ceria particles obtained by manufacturing cerium hydroxide gel by adding an alkali to an aqueous solution of cerium(IV) ammonium nitrate, and then filtering, washing, and firing the manufactured gel; the ceria particles obtained by pulverizing and then firing highly-pure ceria carbonate, and further pulverizing and classifying the pulverized and fired ceria carbonate; and ceria particles obtained by chemically oxidizing a cerium(III) salt in a liquid.

The ceria particles may contain impurities other than ceria. However, the content of ceria in one ceria particle is preferably 80 wt. % or more, more preferably 90 wt. % or more, further preferably 95% or more, and most preferably 100 wt. % (containing no impurities). When the content of ceria in the ceria particles is 80 wt. % or more, it is easy to improve the removal rate of the insulating film.

The average particle size of the abrasive grains is preferably 0.01 μm to 0.5 μm and more preferably 0.03 μm to 0.3 μm. When the average particle size is 0.5 μm or shorter, the mechanical effect on the surface to be polished is reduced, so that the occurrence of polishing damage such as scratches on the surface to be polished is suppressed. Further, when the average particle size is 0.01 μm or longer, the aggregation of abrasive grains is suppressed, so that the storage stability of the polishing agent is excellent and the removal rate is also excellent.

Note that since the abrasive grains exist as aggregated particles (secondary particles) in which primary particles are aggregated in the liquid, the above-described average particle size is the average secondary particle size. The average secondary particle size is measured by using a dispersion liquid in which secondary particles are dispersed in a dispersion medium such as pure water and using a particle-size distribution meter such as a laser diffraction/scattering type meter.

The lower limit value of the content of abrasive grains is preferably 0.01 wt. %, more preferably 0.05 wt. %, still more preferably 0.1 wt. %, and particularly preferably 0.15 wt. % based on the total weight of the polishing agent. When the content of abrasive grains is equal to or higher than the aforementioned lower limit value, an excellent removal rate for the surface to be polished can be obtained. On the other hand, the upper limit value of the content of abrasive grains is preferably 10.0 wt. %, more preferably 8.0 wt. %, still more preferably 5.0 wt. %, particularly preferably 2.0 wt. %, still particularly preferably 1.0 wt. %, extremely preferably 0.8 wt. %, and most preferably 0.5 wt. % based on the total weight of the polishing agent. When the content of abrasive grains is equal to or lower than the upper limit value, the agglomeration of abrasive grains can be suppressed; the increase in the viscosity of the polishing agent disclosed herein can be suppressed; and the handling property is excellent.

The zeta potential (surface potential) of the abrasive grains in the polishing agent is preferably negative (lower than 0 mV), more preferably −200 mV to −10 mV, still more preferably −150 mV to −20 mV, and particularly preferably −100 mV to −30 mV. When the zeta potential of the abrasive grains is within the above-described range, the dispersion stability of the abrasive grains and the flatness of the silicon oxide film after the polishing can be improved.

The zeta potential of the abrasive grains can be measured by using, for example, a dynamic light scattering-type zeta potential measuring apparatus (e.g., Product Name: DelsaNano C manufactured by Beckman Coulter Co., Ltd.). The zeta potential of the abrasive grains can be adjusted by using an anionic polymer, an acidic compound, an additive, or the like (which will be described later).

### <Anionic Polymer>

In the polishing agent disclosed herein, the anionic polymer is a copolymer containing a hydrophobic monomer having a partition coefficient (log D) of 0 to 4, and an anionic monomer containing at least one type selected from unsaturated monocarboxylic acids and salts thereof. Further, the acid value of the anionic polymer is 20 mgKOH/g to 400 mgKOH/g. By using the above-described specific anionic polymer, the polishing of the stopper film is suppressed, so that a high selective ratio between the silicon oxide film and the stopper film can be obtained. The composition of the anionic polymer will be described hereinafter.

### (Hydrophobic Monomer)

In the present disclosure, the hydrophobic monomer refers to a monomer of which the amount that can be dissolved in 100 g of water at 20° C. (hereinafter, it is also referred to as “solubility”) is 10 g or smaller. Among hydrophobic monomers, one having a partition coefficient (log D) of 0 to 4 is selected and used as the anionic polymer. Since the above-described anionic polymer has a constituent unit derived from the hydrophobic monomer, the polishing of the stopper film is suppressed even further. The partition coefficient of the hydrophobic monomer is preferably 0 to 3.

In the present disclosure, the partition coefficient (log D) of the hydrophobic monomer represents the partition coefficient of molecules between the aqueous phase and the lipophilic phase. Specifically, the partition coefficient can be determined by putting a hydrophobic monomer to be measured, water (buffer solution), and an organic solvent (n-octanol) in a container, shaking it sufficiently, separating it into phases, determining the quantity of the hydrophobic monomer in each of the phases, obtaining the concentration of Co in the organic solvent and the concentration of Cw in the water, respectively, and calculating the common logarithm of the concentration ratio (Co/Cw). Regarding the partition coefficient (log D) in the present disclosure, a buffer solution is used as the aqueous phase, and a value when pH is about 5.5 is adopted as the partition coefficient (log D). Note that as for monomers whose partition coefficients are known, values shown in literatures may be used.

In order to improve the selective ratio, the lower limit of log D of the hydrophobic monomer is 0, preferably 0.5, and more preferably 1.0. Further, in order to improve the removal rate of the silicon oxide film, the upper limit of log D of the hydrophobic monomer is 4, preferably 3.5, and more preferably 3.0.

The solubility of the hydrophobic monomer is preferably 7 g or lower, more preferably 5 g or lower, still more preferably 3 g or lower, and particularly preferably 2 g or lower.

Further, the solubility parameter (SP value) of the hydrophobic monomer is preferably 10.5 or lower, more preferably 10.2 or lower, still more preferably 10.0 or lower, still more preferably 9.8 or lower, and particularly preferably 9.6 or lower.

The hydrophobic monomer is preferably a monomer having no ionic group nor hydrophilic group, and more preferably a compound represented by the below-shown Formula (2).

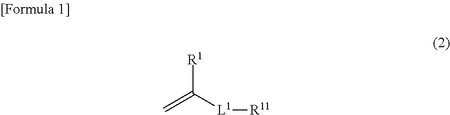

where
R¹ is a hydrogen atom or a methyl group,
R¹¹ is a hydrocarbon group which may have O or Si between carbon and carbon atoms, and the hydrogen atom may be substituted by a halogen atom.
L¹ is a single bond or a divalent linking group.

In the above-shown Formula (2), R¹¹ is a hydrophobic substituent which may have O or Si between carbon and carbon atoms, and the hydrogen atom may be substituted by a halogen atom. Examples of the hydrocarbon group in R¹¹ include an alkyl group, an aryl group, and an aralkyl group. The alkyl group may be linear, branched, or cyclic. Further, the carbon number of the alkyl group is preferably 1 to 18 and more preferably 1 to 12.

Specific examples of the alkyl group include a methyl group, an ethyl group, an n-propyl group, an isopropyl group, an n-butyl group, an isobutyl group, a sec-butyl group, a tert-butyl group, various pentyl groups, various hexyl groups, various octyl groups, various decyl groups, a cyclopentyl group, a cyclohexyl group, a cyclooctyl group, a cyclododecyl group, a bornyl group, and an adamantly group.

Examples of the aryl group include a phenyl group, a biphenyl group, a naphthyl group, a tolyl group, and a xylyl group. The carbon number of the aryl group is preferably 6 to 24 and more preferably 6 to 12.

Further, examples of the aralkyl group include a benzyl group, a phenethyl group, a naphthylmethyl group, and a biphenylmethyl group. The carbon number of the aralkyl group is preferably 7 to 20 and more preferably 7 to 14.

When R¹¹ has an aromatic ring, the hydrogen atom of this aromatic ring may have, for example, a substituent such as a linear or branched alkyl group having a carbon number of 1 to 4.

The hydrocarbon group in R¹¹ may further have O or Si between carbon and carbon atoms, and the hydrogen atom may be substituted by a halogen atom.

Examples of the hydrocarbon group having O or Si between carbon and carbon atoms include alkylene oxides such as —(CH₂CH₂O)ₓ— and —(CH₂O)ₓ—, and —CH₂Si(R¹²)₂—CH₂—. Note that x represents the number of repeating units, and is preferably an integer of 1 to 18. Further, each of two R¹² is independently a hydrogen atom or a methyl group.

Further, regarding R¹¹, the hydrogen atom of the hydrocarbon group of the above-described structure may be substituted by a halogen atom. Examples of halogen atoms include F, Cl, Br and I.

R¹¹ is preferably a hydrocarbon group containing none of O, Si, and a halogen atom in view of hydrophobicity and availability.

L¹ is a single bond or a divalent linking group connecting an unsaturated double bond and R¹¹. Examples of L¹ include an alkylene group having a carbon number of 1 to 8, —(CH₂CH₂O)ₓ—, —(CH₂O)ₓ—, —CONH—, —COO—, and —C(═O)—. Examples of the alkylene group having a carbon number of 1 to 8 include a methylene group, an ethylene group, a propylene group, a butylene group, a pentylene group, a hexylene group.

L¹ is preferably a single bond. —CONH—, or COO— in view of availability.

Only one type of hydrophobic monomer can be used, or two or more types of hydrophobic monomers can be used in combination. The hydrophobic monomer may be a combination of a monomer having a ring structure and a monomer having no ring structure in view of the dispersibility in the polishing agent.

Specific examples of hydrophobic monomers include alkyl (meth)acrylates such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, n-pentyl (meth)acrylate, isopentyl (meth)acrylate, n-hexyl (meth)acrylate, 2-ethylhexyl (meth)acrylate, isooctyl (meth)acrylate, n-dodecyl (meth)acrylate, and stearyl (meth)acrylate; (meth)acrylates having a ring structure such as 1-methylcyclopentyl acrylate, cyclohexyl (meth)acrylate, and benzyl (meth)acrylate;
vinyl-based monomers such as styrene, methylstyrene, vinyltoluene, p-t-butylstyrene, chloromethylstyrene, vinyl chloride, vinylidene chloride, vinyl fluoride, and vinylidene fluoride. Among them, alkyl (meth)acrylate is preferably contained, and alkyl (meth)acrylate having an alkyl group having a carbon number of 1 to 6 is more preferred.

### (Anionic Monomer)

In the present disclosure, the anionic monomer includes at least one type selected from unsaturated monocarboxylic acids and salts thereof (hereinafter also referred to as unsaturated carboxylic acids and the like). Since the above-described anionic polymer has a constituent unit derived from an unsaturated monocarboxylic acid, the carboxy group is adsorbed onto the stopper film, and the anionic polymer acts as a protective film of the stopper film.

The anionic monomer is preferably a monomer having no ionic group nor hydrophilic group, and more preferably a compound represented by the below-shown Formula (3).

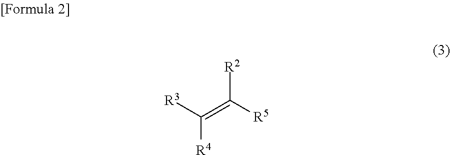

where
R², R³, and R⁴ are each independently a hydrogen atom or a hydrocarbon group.
R⁵ is a carboxy group or a group having a salt thereof.

Examples of hydrocarbon groups in R² to R⁴ include an alkyl group, an aryl group, and an aralkyl group. Specific examples of an alkyl group, an aryl group, and an aralkyl group are similar to those for R¹¹. In the polishing agent disclosed herein, in view of the interaction between the carboxy group and the stopper film, the hydrocarbon group in R² to R⁴ is preferably an alkyl group having a carbon number of 1 to 18, more preferably an alkyl group having a carbon number of 1 to 6, still more preferably a methyl group or ethyl group, and still more preferably a methyl group.

The carboxy group or the group having a salt thereof in R⁵ preferably has a structure of -L²-R²¹.

The above-described L² is a single bond or a divalent linking group connecting an unsaturated double bond and R²¹. Examples of L² include an alkylene group having a carbon number of 1 to 8, a phenylene group, —(CH₂CH₂O)ₓ—R²²—, —(CH₂O)ₓ—R²²—, —CONH—R²²—, and —COO—R²²—. Note that x is an integer of 1 to 18, and R²² is preferably a single bond or an alkylene group having a carbon number of 1 to 8.

Examples of the alkylene group in L² and R²² include a methylene group, an ethylene group, a propylene group, a butylene group, a pentylene group, and a hexylene group, and may have a halogen atom as a substituent.

L² is preferably a single bond, an alkylene group, or a phenylene group in view of the availability of monomers.

R²¹ is a carboxy group or a salt thereof.

When the carboxy group is a salt, examples of the counter cation include alkali metal ions, alkaline earth metal ions, and ammonium ions.

Examples of suitable combinations of R² to R⁵ in Formula (3) include: (I) a combination in which: R² is hydrogen or a methyl group; R³ to R⁴ are hydrogen atoms; and R⁵ is a carboxy group or the like (acrylic acid or methacrylic acid); (II) a combination in which: R² and R³ are hydrogen atoms; R⁴ is hydrogen or an alkyl group; R⁵ is -L²-R²¹; and L² is an alkylene group (unsaturated fatty acid); and (III) a combination in which R² to R⁴ are hydrogen atoms; R⁵ is -L²-R²¹; and L² is a phenylene group (vinyl benzoic acid).

Specific examples of the anionic monomer represented by Formula (3) include (meth)acrylic acid, vinyl benzoic acid, 2-carboxyethyl (meth)acrylate, and unsaturated fatty acid. Only one type of anionic monomer may be used, or two or more types of anionic monomers may be used in combination.

Further, the anionic monomer may contain anionic monomers other than unsaturated monocarboxylic acid as long as the effects of the embodiment are achieved. Examples of other anionic monomers include allylsulfonic acid, metallylsulfonic acid, 2-(meth)acryloyloxyethyl acid phosphate, maleic acid (maleic anhydride), fumaric acid, itaconic acid, citraconic acid, and mesaconic acid.

The ratio of the other anionic monomers is preferably 5 mol % or lower, more preferably 2 mol % or lower, still more preferably 1 mol % or lower based on the total amount of the anionic monomers, and particularly preferably, they are substantially not contained.

### (Other Monomers)

Further, the anionic polymer may contain monomers other than the hydrophobic monomer and the anionic monomer as long as the effects of the embodiment are achieved.

Examples of other monomers include (meth)acrylamide derivatives such as (meth)acrylamide, N,N-dimethyl (meth)acrylamide, N,N-diethyl (meth)acrylamide, N,N-dibutyl (meth)acrylamide, N-tert-butyl acrylamide, N-phenyl (meth)acrylamide, and N-benzyl (meth)acrylamide. The ratio of the other monomers is preferably 5 mol % or lower, more preferably 1 mol % or lower, and still more preferably 0.5 mol % or lower based on the total of the whole monomers constituting the anionic polymer.

### (Physical Property of Anionic Polymer)

In the polishing agent disclosed herein, the acid value of the anionic polymer is 20 mgKOH/g to 400 mgKOH/g. By using an anionic polymer having an acid value of 400 mgKOH/g or lower, the selective ratio between the silicon oxide film and the stopper film is improved. Further, by using an anionic polymer having an acid value of 20 mgKOH/g or higher, the anionic polymer gets easily adsorbed on the abrasive grains, so that the agglomeration of the abrasive grains is suppressed. Further, the solubility of the anionic polymer is improved, so that the agglomeration of anionic polymers is also suppressed.

The lower limit of the acid value of the anionic polymer is preferably 50 mgKOH/g, more preferably 100 mgKOH/g, and still more preferably 150 mgKOH/g in order to suppress the agglomeration of the abrasive grains. Further, the upper limit of the acid value of the anionic polymer is preferably 350 mgKOH/g, more preferably 300 mgKOH/g, and still more preferably 280 mgKOH/g in order to improve the selective ratio. Note that the acid value represents the mass (mg) of potassium hydroxide required to neutralize the acidic components contained in 1 g of the solid content of the polymer, and is a value measured by a method described in JIS K 0070:1992.

In the above-described anionic polymer, the ratio between the hydrophobic monomer and the anionic monomer may be adjusted as appropriate so that its acid value falls within the above-described range. As an example, the ratio of the hydrophobic monomer is preferably 10 mol % or higher, more preferably 20 mol % or higher, still more preferably 30 mol % or higher, and particularly preferably 40 mol % or higher based on the total of the whole monomers constituting the anionic polymer. By adjusting the content of the hydrophobic monomer to 10 mol % or higher, the polishing of the stopper film can be suppressed even further. Further, in the above-described anionic polymer, the ratio of the hydrophobic monomer is preferably 95 mol % or lower, more preferably 90 mol % or lower, still more preferably 85 mol % or lower, and particularly preferably 80 mol % or lower based on the total of the whole monomers. By adjusting the content of the hydrophobic polymer at 95 mol % or lower, the solubility of the anionic polymer is improved, so that the agglomeration of the abrasive grains and the agglomeration of the anionic polymer are suppressed.

The above-described anionic polymer may be a random polymer in which the above-described hydrophobic monomer and the above-described anionic monomer are randomly arranged, or a block polymer having blocks of the anionic polymer and blocks of the anionic monomer.

The solubility of the above-described anionic polymer in water is preferably 5 mg/100 g-H₂O or higher and more preferably 10 mg/100 g-H₂O or higher at 25° C. in view of the storage stability and the like.

The weight-average molecular weight Mw of the anionic polymer is preferably 1,000 to 100,000 in view of the dispersion stability of the anionic polymer. In particular, the lower limit of the weight-average molecular weight Mw of the anionic polymer is preferably 2,000, more preferably 2,500, and still more preferably 3,000. Further, the upper limit of the weight-average molecular weight Mw of the anionic polymer is preferably 50,000, more preferably 40,000, still more preferably 30,000, still more preferably 25,000, particularly preferably 20,000, and extremely preferably 17,500. Regarding the weight-average molecular weight (Mw), its standard polystyrene equivalent value is obtained by gel permeation chromatography (GPC).

For the above-described anionic polymer, a commercially available product may be used, or the anionic polymer may be synthesized. For example, in the case of a random polymer, the anionic polymer can be polymerized, by a known polymerization method such as solution polymerization, bulk polymerization, or other various radical polymerization, by mixing a hydrophobic monomer and an anionic monomer, and adding an initiator in the mixture. Among them, solution polymerization is preferred because the weight-average molecular weight of the copolymer can be easily adjusted. Further, in the case of a block polymer, for example, an anionic block may be synthesized first and a hydrophobic monomer may be polymerized into this anionic block. In this manufacturing method, the order of polymerizations of the anionic block and the hydrophobic block may be reversed. Further, an anionic block and a hydrophobic block may be separately synthesized, and then the anionic block and the hydrophobic block may be coupled to each other.

The content of the anionic polymer is preferably from 0.02 wt. % to 0.5 wt. %, more preferably from 0.05 wt. % to 0.45 wt. %, still more preferably from 0.08 wt. % to 0.4 wt. %, and particularly preferably from 0.1 wt. % to 0.35 wt. % based on the total weight of the polishing agent.

### <Acidic Compound>

The polishing agent disclosed herein contains an acidic compound selected from phosphoric acid compounds and organic acid compounds. By containing this acidic compound, it is possible to suppress the removal rate of the stopper film while maintaining the removal rate of the silicon oxide film. Note that the molecular weight of this acidic compound is preferably 1,000 or lower.

Specific examples of phosphoric acid compounds include phosphoric acid, phosphorous acid, phosphonic acid, phosphinic acid, and their ammonium salts, and their alkali metal salts.

Examples of organic acid compounds include compounds having a carboxy group, a sulfo group, a phospho group, an ammonium salt of these groups, or an alkali metal salt of these groups. Among them, an organic acid compound having a carboxy group is preferred.

Examples of organic acid compounds having a carboxy group include alkyl monocarboxylic acids such as formic acid, acetic acid, and propionic acid;
carboxylic acids having a heterocycle such as 2-pyridinecarboxylic acid, 3-pyridinecarboxylic acid, 4-pyridinecarboxylic acid, 2,3-pyridinedicarboxylic acid, 2,4-pyridinedicarboxylic acid, 2,5-pyridinedicarboxylic acid, 2,6-pyridinedicarboxylic acid, 3,4-pyridinedicarboxylic acid, 3,5-pyridinedicarboxylic acid, pyrazinecarboxylic acid, 2,3-pyrazinedicarboxylic acid, 2-quinolinecarboxylic acid, pyroglutamic acid, picolinic acid, DL-pipecolic acid, 2-furancarboxylic acid, 3-furancarboxylic acid, tetrahydrofuran-2-carboxylic acid, and tetrahydrofuran-2,3,4,5-tetracarboxylic acid;
alicyclic carboxylic acids such as cyclopentanecarboxylic acid, cyclohexanecarboxylic acid, cycloheptanecarboxylic acid, and cyclohexylcarboxylic acid;
carboxylic acids containing an amino group such as alanine, glycine, glycylglycine, aminobutyric acid, N-acetylglycine, N,N-di(2-hydroxyethyl)glycine, N-(tert-butoxycarbonyl)glycine, proline, trans-4-hydroxy-L-proline, phenylalanine, sarcosine, hydantoic acid, creatine, N-[tris(hydroxymethyl)methyl]glycine, glutamic acid, and aspartic acid;
carboxylic acids containing a hydroxyl group such as lactic acid, malic acid, citric acid, tartaric acid, glycolic acid, gluconic acid, salicylic acid, 2-hydroxyisobutyric acid, glyceric acid, 2,2-bis(hydroxymethyl)propionic acid, and 2,2-bis(hydroxymethyl)butyric acid;
carboxylic acids (keto acids) such as pyruvic acid, acetoacetic acid, and levulinic acid; and
dicarboxylic acids such as oxalic acid, malonic acid, succinic acid, fumaric acid, maleic acid, glutaric acid, adipic acid, and phthalic acid.

Among them, dicarboxylic acid is particularly preferred as the organic acid compound having a carboxy group.

Only one type of acidic compound may be used, or two or more types of acidic compounds may be used in combination. When only one type of acidic compound is used, the above-described acidic compound may also be referred to as a first acidic compound. Further, when two or more types of acidic compounds are used in combination, the compound having the highest molarity among the plurality of acidic compounds may be referred to as a first acidic compound.

The ratio of the first acidic compound to the total amount of the acidic compounds is preferably 30 mol % or higher, more preferably 50 mol % or higher, and still more preferably 70 mol % or higher.

The acid dissociation constant pKa of the first acidic compound is preferably 4 to 9, more preferably 4.5 to 7, and still more preferably 5 to 6.5. By using an acidic compound having an acid dissociation constant of 4 to 9 as the first acidic compound, it becomes easy to prepare a polishing agent that satisfies a relationship represented by Formula (1) (which will be described later), and to improve the selective ratio. When an acidic compound has two or more acid dissociation constants, at least one of them should be 4 to 9. The acid dissociation constant may be measured by neutralization titration, or values shown literatures may be used.

The polishing agent disclosed herein uses the above-described pKa of the first acidic compound and pH of the polishing agent that satisfy the relationship represented by Formula (1).

$$\vert pKa - pH \vert \leq 1.5 \qquad ( 1 )$$

where when the first acidic compound has two or more acid dissociation constants, pKa represents an acid dissociation constant closest to pH.

By using a polishing agent of which the absolute value of the difference between pKa and pH is 1.5 or smaller, a high selective ratio between the silicon oxide film and the stopper film can be obtained; the storage stability is excellent; and changes in pH and viscosity are suppressed even when the polishing agent is stored for a long time. Note that the inventors of the present application infer that the first acidic compound having the highest concentration among the acidic compounds has a large influence on the above-described effects, and for pKa, it is appropriate to refer to the value of the first acidic compound.

In order to improve the selective ratio of the polishing agent, |pKa−pH| is preferably 1.2 or smaller, more preferably 1.0 or smaller, still more preferably 0.9 or smaller, still more preferably 0.8 or smaller, particularly preferably 0.7 or smaller, extremely preferably 0.6 or smaller, and most preferably 0.5 or smaller.

Examples of the method for preparing a polishing agent satisfying Formula (1) include, in addition to the method for adjusting pKa by selecting the first acidic compound, a method for adjusting the concentration of the first acidic compound, a method for adjusting pH by adding an acidic compound other than the first acidic compound or other types of pH adjusting agent or the like.

The ratio of the acidic compound in the polishing agent is preferably 0.001 wt. % to 2.0 wt. %, more preferably 0.005 wt. % to 1.0 wt. %, and still more preferably 0.01 wt. % to 0.3 wt. % based on the whole polishing agent.

### <Water>

The polishing agent disclosed herein contains water as a medium in which abrasive grains are dispersed. The type of water is not limited to any particular types. However, it is preferred to use pure water, ultrapure water, ion exchange water, or the like in consideration of the effects on other components, the prevention of the contamination by impurities, and the effects on pH and the like.

### <Nonionic Polymer>

Further, the polishing agent disclosed herein may contain a nonionic polymer. The nonionic polymer is preferably a nonionic polymer having an ether bond, and more preferably a nonionic polymer containing an ether bond in the main chain in view of the lubricity. Examples of nonionic polymers include polyethylene glycol, polyglycerol, and water-soluble nylon.

When a nonionic polymer is used, its content ratio may be 0.005 wt. % to 2.0 wt. %, preferably 0.01 wt. % to 1.5 wt. %, and still more preferably 0.01 wt. % to 0.3 wt. % based on the whole polishing agent disclosed herein. When the content of the nonionic polymer is within the above-described range, the wettability of the polishing agent for the surface to be polished is improved, and the removal rate of the silicon oxide film is improved because the polishing agent comes into contact with the abrasive grains more frequently.

### <Additive>

The polishing agent disclosed herein may also contain various additives. Examples of additives include a pH adjusting agent, a dispersant, an agglomeration inhibitor, a lubricant, a viscosity imparting agent, a viscosity adjusting agent, and a preservative. Further, the polishing agent may contain two or more types of additives. Note that although the above-described phosphoric acid compounds and organic acid compounds can be included in the pH adjusting agents, they are not included in the pH adjusting agents in the present disclosure.

### (pH Adjusting Agent)

The polishing agent may contain a pH adjusting agent in order to adjust its pH to a predetermined value. The pH adjusting agent may be selected as appropriate from among acidic compounds other than the phosphoric acid compounds and the organic acid compounds, basic compounds, amphoteric compounds such as amino acid, and salts thereof, and used as appropriate.

Examples of the acidic compounds other than the phosphoric acid compounds and the organic acid compounds include inorganic acids or salts thereof. Examples of inorganic acids include nitric acid, sulfuric acid, and hydrochloric acid. Further, their ammonium salts, sodium salts, potassium salts, or the like may be used. When an inorganic acid is used, it is preferred to use it within a range in which the molar concentration in the polishing agent does not become higher than that of the first acidic compound.

Examples of basic compounds include ammonia, sodium hydroxide, potassium hydroxide, ammonium hydroxide, potassium carbonate, sodium carbonate, and ammonium carbonate; quaternary ammonium hydroxides such as tetramethylammonium hydroxide, and tetraethylammonium hydroxide; and amino alcohols such as monoethanolamine, diethanolamine, and triethanolamine.

Further, examples of amphoteric compounds include glycine, alanine, and phenylalanine.

Only one type of pH adjusting agent may be used, or two or more types of pH adjusting agents may be used in combination. The pH of the polishing agent disclosed herein is preferably 4 to 9. The lower limit of pH is more preferably 4.5, still more preferably 5, and particularly preferably 6. Further, the upper limit of pH is preferably 8.5, more preferably 8, still more preferably 7.5, and particularly preferably 7. By adjusting pH within the above-described range, the agglomeration of abrasive grains can be suppressed and the selective ratio can be improved.

The content ratio of the pH adjusting agent may be adjusted as appropriate so that the aforementioned pH is achieved. As an example, the content ratio can be adjusted to 0.005 wt. % to 2.0 wt. %, preferably 0.01 wt. % to 1.5 wt. %, more preferably 0.01 wt. % to 0.3 wt. % based on the whole polishing agent disclosed herein.

### (Dispersant)

The polishing agent disclosed herein may contain a dispersant in order to improve the dispersibility of abrasive grains. Examples of dispersants include anionic surfactants, cationic surfactants, nonionic surfactants, and amphoteric surfactants. Only one type of dispersant may be used, or two or more types of dispersants may be used.

The anionic surfactant is preferably a polymer having a carboxy group, an ammonium carboxylate, or the like, and more preferably polyacrylic acid or polyacrylate.

Examples of cationic surfactants include a diallyldimethylammonium chloride polymer, a diallyldimethylammonium chloride/sulfur dioxide copolymer, a diallyldimethylammonium chloride/acrylamide copolymer, a diallyldimethylammonium chloride/maleic acid copolymer, and a maleic acid/diallyldimethylammonium ethyl sulfate/sulfur dioxide copolymer.

The weight-average molecular weight of the above-described surfactant is preferably 10,000 to 100,000 in order to polish the surface to be polished at a higher speed.

When a dispersant is used, its content is preferably 0.0001 wt. % to 0.3 wt. %, more preferably 0.001 wt. % to 0.2 wt. %, and still more preferably 0.01 wt. % to 0.15 wt. % based on the total weight of the polishing agent in order to polish the surface to be polished at a higher speed.

When the above-described additives are used in the polishing agent disclosed herein, the total content of the additives is preferably 0.01 to 10.0 wt. % and still more preferably 0.01 to 5.0 wt. % based on the total weight of the polishing agent in order to obtain a polishing agent having a high selective ratio between the silicon oxide film and the stopper film.

The method for preparing the polishing agent disclosed herein may be selected as appropriate from among methods in which each of the components that are used as required, i.e., abrasive grains, an anionic polymer, and an acidic compound, is uniformly dispersed or dissolved in water which is the medium.

For example, the polishing agent disclosed herein may be prepared by separately preparing a dispersion liquid of abrasive grains and an additive solution for a polishing agent (which will be described later), and mixing them. According to this method, the storage stability of the above-described dispersion liquid and the additive solution for a polishing agent is improved and the transportation of them become easier.

It is preferred to prepare a polishing agent according to the present disclosure by performing the above-described mixing in a polishing apparatus.

### [Additive Solution for Polishing Agent]

The additive solution for a polishing agent according to this embodiment is an additive solution for preparing a polishing agent by mixing it with a dispersion liquid of abrasive grains as described above, and is an additive solution for a polishing agent containing an anionic polymer, an acidic compound selected from phosphoric acid compounds and organic acid compounds, and water, in which
the anionic polymer is a copolymer containing a hydrophobic monomer and an anionic monomer,
an acid value of the anionic polymer is 20 mgKOH/g to 400 mgKOH/g,
a partition coefficient (log D) of the hydrophobic monomer is 0 to 4,
the anionic monomer contains at least one type selected from unsaturated monocarboxylic acids and salts thereof,
when an acid compound having a highest molar concentration among the acidic compounds is defined as a first acidic compound,
pKa of the first acidic compound and pH of the additive solution for the polishing agent satisfy a relationship expressed by the above-described Formula (1), and the additive solution for the polishing agent may contain, as required, an additive described above as another component in the above-described polishing agent. Note that each of these components is as described above, and therefore descriptions thereof are omitted here.

Note that when a polishing agent is prepared by separately preparing two liquids, i.e., a liquid in which abrasive grains are dispersed and an additive solution for a polishing agent, and then mixing them with each other, it is possible to prepare a liquid in which abrasive grains are dispersed at a concentration 2 to 100 times higher than a predetermined concentration and an additive solution for a polishing agent in which the concentrations of the anionic polymer and the acidic compound are 2 to 100 times higher than predetermined concentrations, and then dilute them to the predetermined concentrations when the polishing agent is used. More specifically, for example, when the concentration of abrasive grains in the dispersion liquid and the concentrations of the anionic polymer and the acidic compound in the additive solution are both 10 times their respective predetermined concentrations, a polishing agent is obtained by mixing 10 pts·mass of the dispersion liquid, 10 pts·mass of the additive solution for a polishing agent, and 80 pts·mass of water with each other, and stirring the mixture.

By adding the above-described additive solution for a polishing agent to the dispersion liquid of the abrasive grains, it is possible to obtain a polishing agent capable of, while maintaining the high removal rate of the silicon oxide film, suppressing the removal rate of the stopper film and achieving a high selective ratio and high flatness.

In the above-described additive solution for a polishing agent, the content ratio (concentration) of the anionic polymer is preferably 0.001 to 30 wt. %, more preferably 0.01 to 20 wt. %, and still more preferably 0.1 to 10 wt. % based on the whole additive solution.

Further, in the above-described dispersion liquid of abrasive grains, the content ratio of the abrasive grains is preferably 0.2 to 40 wt. %, more preferably 1 to 20 wt. %, and still more preferably 5 to 10 wt. %.

### [Polishing Method]

The polishing method according to the present disclosure is a method for polishing a surface to be polished containing silicon oxide of a semiconductor substrate by bringing a polishing pad into contact with the surface to be polished while supplying a polishing agent therebetween, and polishing the surface to be polished by relative motion of the surface to be polished and the polishing pad.

Note that examples of the surface to be polished include a surface made of silicon dioxide of a semiconductor substrate, a blanket wafer in which a stopper film and a silicon oxide film are laminated on a surface of a semiconductor substrate, and a patterned wafer in which these films are arranged in a pattern. Preferred examples of semiconductor substrates include a substrate for STI. The polishing agent according to the present disclosure is also effective for polishing for flattening an interlayer insulating film between multilayer wiring lines in the manufacture of semiconductor devices.

Examples of silicon oxide films in substrates for STI include so-called a PE-TEOS film formed by a plasma CVD method by using tetraethoxysilane (TEOS) as a raw material. Further, examples of silicon oxide films include so-called an HDP film formed by a high-density plasma CVD method. Further, HARP films and FCVD films formed by other CVD methods, and SOD films formed by spin coating can also be used. Examples of silicon nitride films include those formed by a low-pressure CVD method or a plasma CVD method by using silane or dichlorosilane and ammonia as raw materials, and those formed by an ALD method. Further, examples of polysilicon films are those that are formed by a low-pressure CVD method or a plasma CVD method by using silane as a raw material, and then converted into polycrystalline grains by performing a heat treatment.

A known polishing apparatus can be used for the polishing method according to the present disclosure. FIG. 2 is a schematic diagram showing an example of a polishing apparatus. A polishing apparatus 20 shown in the example shown in FIG. 2 includes a polishing head 22 that holds a semiconductor substrate 21 such as an STI substrate, a polishing table 23, a polishing pad 24 bonded to the surface of the polishing table 23, and a polishing agent supply pipe 26 through which a polishing agent 25 is supplied to the polishing pad 24. The polishing apparatus 20 is configured so as to polish the surface to be polished of the semiconductor substrate 21 held by the polishing head 22 by bringing the surface to be polished into contact with the polishing pad 24 while supplying the polishing agent 25 through the polishing agent supply pipe 26, and rotationally moving the polishing head 22 and the polishing table 23 relative to each other.

The polishing head 22 may perform not only the rotational movement but also a linear movement. Further, the polishing table 23 and the polishing pad 24 may have sizes roughly equal to or smaller than that of the semiconductor substrate 21. In this case, it is preferred that the polishing head 22 and the polishing table 23 are moved relative to each other, so that the entire surface to be polished of the semiconductor substrate 21 can be polished. Further, the polishing table 23 and the polishing pad 24 do not necessarily have to be those that perform rotational movements. That is, each of them may instead be, for example, moved in one direction by a belt or the like.

Although the polishing conditions of the polishing apparatus 20 are not limited to any particular conditions, it is possible to improve the removal rate by applying a load to the polishing head 22 and thereby pressing the polishing head 22 against the polishing pad 24, and thereby increasing the polishing pressure applied thereto. The polishing pressure is preferably about 0.5 kPa to 50 kPa, and still more preferably about 3 kPa to 40 kPa in view of the uniformity and flatness on the surface to be polished of the semiconductor substrate 21 at the removal rate, and to prevent polishing defects such as scratches. The rotation speeds of the polishing table 23 and the polishing head 22 are preferably about 50 rpm to 500 rpm. Further, the amount of the polishing agent 25 to be supplied is adjusted as appropriate according to the composition of the polishing agent, the above-described polishing conditions, and the like.

As the polishing pad 24, one made of a nonwoven fabric, a foamed polyurethane, a porous resin, a nonporous resin, or the like can be used. In order to increase the supply of the polishing agent 25 to the polishing pad 24 or to make a certain amount of the polishing agent 25 remain in the polishing pad 24, grooves in a lattice pattern, a concentric circular pattern, a spiral pattern, or the like may be formed in the surface of the polishing pad 24 by machining or the like. Further, if necessary, a pad conditioner may be brought into contact with the surface of the polishing pad 24, so that the surface to be polished is polished while the surface of the polishing pad 24 is constantly conditioned.

According to the polishing method in accordance with the present disclosure, it is possible to obtain a high selective ratio between the silicon oxide film and the stopper film while suppressing polishing damage, and to carry out polishing with high flatness.

### [Method of Manufacturing Semiconductor Component]

The method for manufacturing a semiconductor component according to this embodiment is one in which a semiconductor component is obtained by dividing a semiconductor substrate having a surface to polished, polished by the polishing method according to the present disclosure into pieces.

The method for manufacturing a semiconductor component according to the present disclosure includes at least a dividing step of dividing a semiconductor substrate having a surface to polished, polished by the above-described polishing method into pieces. The dividing step includes, for example, a step of obtaining a semiconductor component, which is a semiconductor chip, by dicing the semiconductor substrate (e.g., a semiconductor wafer) by a known method such as blade dicing, laser dicing, or plasma dicing.

The method for manufacturing a semiconductor component may further include a joining step of joining another member on the surface to be polished of the semiconductor chip. By this step, a semiconductor component, which is an assembly, is obtained.

Examples of other members include a second semiconductor chip and a re-wiring layer. Note that the second semiconductor chip may be a semiconductor chip obtained by the manufacturing method according to the present disclosure, or a semiconductor chip obtained by other methods. The joining step may be, for example, a step in which another member is directly disposed on the surface to be polished and directly joined by fusion bonding, surface activation bonding, or the like, or a step in which the surface to be polished and another member are joined with an adhesive layer therebetween. Examples of the adhesive layer include a metal layer such as a solder layer and a copper layer, a glass layer, and a resin layer such as a polyimide layer and an epoxy layer.

The present disclosure can also provide an electronic device including at least one semiconductor component having a surface to be polished, polished by the polishing method according to the present disclosure.

### EXAMPLES

The present invention will be described hereinafter in a more detailed manner with reference to examples and comparative examples, but the present invention is not limited to these examples. Examples 1 to 8 are examples according to the present disclosure, and Examples 9 to 14 are comparative examples.

### [Measuring Method]

<pH>

The pH was measured at a temperature of 25±5° C. by using a pH meter HM-30R manufactured by DKK-TOA Corporation.

### <Average Secondary Particle Size>

The average secondary particle size was measured by using a laser scattering/diffraction type particle-size distribution measurement apparatus (manufactured by HORIBA, Ltd., apparatus name: LA-950).

### <Acid Value>

Acid values were measured by a method described in JIS K 0070:1992.

### <Weight-Average Molecular Weight (Mw)>

The weight-average molecular weight was measured by gel permeation chromatography (GPC) under the following conditions.
Apparatus HLC-8320GPC (manufactured by TOSOH Corporation)
Column TSKgel GMPWXL (manufactured by TOSOH Corporation)
Detector RI Detector polarity (+)
Eluent 0.2M-NaNO₃ aqueous solution
Flow rate 1.0 mL/min column temperature 40° C.
Calculated in terms of Standard PEO/PEG

### [Polishing Agent]

### <Abrasive Grains>

Ceria particles having a particle size of 50 to 150 nm were used as abrasive grains. The content ratio of ceria in the ceria particles was 95 wt. % or higher.

### <Anionic Polymer>

An anionic polymer having the following composition was prepared.
Anionic polymer (A): A polymer consisting of 70 mol % n-butyl methacrylate (log D: 2.6) and 30 mol % methacrylic acid, having an acid value of 150 mgKOH/g and a weight-average molecular weight of 20,000.
Anionic polymer (B): A polymer consisting of 50 mol % n-butyl methacrylate and 50 mol % methacrylic acid, having an acid value of 250 mgKOH/g and a weight-average molecular weight of 20,000.
Anionic polymer (C): A polymer consisting of 50 mol % n-butyl methacrylate and 50 mol % methacrylic acid, having an acid value of 250 mgKOH/g and a weight-average molecular weight of 15,000.
Anionic polymer (D): A polymer that is a homopolymer of methacrylic acid, having an acid value of 650 mgKOH/g and a weight-average molecular weight of 10,000.
Anionic polymer (E): A polymer consisting of 10 mol % n-butyl methacrylate and 90 mol % methacrylic acid, having an acid value of 510 mgKOH/g and a weight-average molecular weight of 20,000.
Anionic polymer (F): A polymer consisting of 30 mol % decyl methacrylate (log D is 5.9) and 70 mol % methacrylic acid, having an acid value of 300 mgKOH/g and a weight-average molecular weight of 40,000.

### <Preparation of Polishing Agent>

As shown in Table 1, each of polishing agents of Examples 1 to 14 was prepared by mixing abrasive grains, an anionic polymer, an acidic compound, other components, and water. In each polishing agent, the zeta potential of the abrasive grains was −80 mV to −50 mV. Note that the acidic compound was prepared in a range of 0.01 wt. % to 0.3 wt. % in consideration of pH. Further, a symbol “−” in Table 1 indicates that no material was used.

### [Polishing Evaluation]

### <Polishing Condition>

The performance of each of the polishing agents according to Examples 1 to 14 was evaluated by using a fully automatic CMP apparatus FREX300X (Ebara Corporation). In the evaluation, a polyurethane pad (IC-1000 manufactured by DuPont) was used as the polishing pad, and a diamond pad conditioner (manufactured by 3M, Product Name: A165) was used for the conditioning of the polishing pad. Regarding the polishing conditions, the polishing pressure was 21 kPa; the rotation speed of the polishing table was 100 rpm; and the rotation speed of the polishing head was 102 rpm. Further, the supplying rate of the polishing agent was 250 ml/min, unless otherwise specified.

Each of the following objects was used as the polishing target object (object to be polished).
A blanket wafer with a silicon dioxide film formed by a plasma CVD method by using tetraethoxysilane (TEOS) as a raw material on a 12-inch silicon substrate
A blanket wafer with a silicon nitride film formed by a low-pressure CVD method by using silane and ammonia as raw materials on a 12-inch silicon substrate

### <Evaluation Method>

A film thickness meter VM-3210 manufactured by SCREEN Holdings Co., Ltd. was used for the measurement of the thicknesses of the formed silicon dioxide films and silicon nitride films. For each blanket wafer, the removal rate of each of the silicon dioxide film and the silicon nitride film was calculated by obtaining a difference between the film thickness before being polished and the film thickness after being polishing for one minute. An average value (Å/min) of removal rates obtained from removal rates at 49 points on the surface of the substrate was defined as the removal rate. Then, the ratio of the removal rate of the silicon dioxide film to that of the silicon nitride film (removal rate of the silicon dioxide film/removal rate of the silicon nitride film) was calculated as the selective ratio. Table 1 shows the results. Note that in the table, the silicon oxide film is expressed as “TEOS” and the silicon nitride film is expressed as “SiN”.

### [Stability Evaluation]

For each of the polishing agents in Examples 1 to 14, pH was measured after it had been stored at 50° C. for two weeks. Table 1 shows, for each polishing agent, a difference between pH of the polishing agent immediately after the preparation and pH after being stored.

TABLE 1

| | Component, etc. | | Example 1 | Example 2 | Example 3 | Example 4 | Example 5 | Example 6 | Example 7 |
|---|---|---|---|---|---|---|---|---|---|
| Abrasive | Abrasive | Type | Celia | Celia | Celia | Celia | Celia | Celia | Celia |
| agent | grain | Content | 0.175 | 0.175 | 0.175 | 0.175 | 0.175 | 0.175 | 0.175 |
| | | (mass %) | | | | | | | |
| | Anionic | Type | (A) | (B) | (A) | (B) | (B) | (C) | (B) |
| | polymer | Content | 0.05 | 0.05 | 0.05 | 0.05 | 0.05 | 0.05 | 0.05 |
| | | (mass %) | | | | | | | |
| | Acidic | Type | malonic | malonic | maleic acid | succinic | maleic acid | succinic | succinic |
| | compound | pKa | 5.7 | 5.7 | 6.2 | 5.6 | 6.2 | 5.6 | 5.6 |
| | Nonionic | Type | — | — | — | — | — | — | polyglycerin |
| | polymer | Content | — | — | — | — | — | — | 0.05 |
| | | (mass %) | | | | | | | |
| | pH | | 6 | 6 | 6.6 | 5.6 | 5.6 | 5.6 | 5.6 |
| | \|pKa-pH\| | | 0.3 | 0.3 | 0.4 | 0 | 0.6 | 0 | 0 |
| Results | Polishing | TEOS(Å/min) | 1818 | 1742 | 1916 | 1591 | 1418 | 1547 | 1706 |
| | evaluation | SiN(Å/min) | 16 | 45 | 29 | 35 | 36 | 33 | 30 |
| | | TEOS/SiN | 114 | 39 | 66 | 45 | 39 | 47 | 57 |
| | | selective ratio | | | | | | | |

| | | | | | | | |
|---|---|---|---|---|---|---|---|
| pH change | 0.08 | 0.06 | 0.06 | 0.06 | 0.07 | 0.06 | 0.07 |

| | Component, etc. | | Example 8 | Example 9 | Example 10 | Example 11 | Example 12 | Example 13 | Example 14 |
|---|---|---|---|---|---|---|---|---|---|
| Abrasive | Abrasive | Type | Celia | Celia | Celia | Celia | Celia | Celia | Celia |
| agent | grain | Content | 0.175 | 0.175 | 0.175 | 0.175 | 0.175 | 0.175 | 0.175 |
| | | (mass %) | | | | | | | |
| | Anionic | Type | (B) | (D) | (E) | (F) | (B) | (B) | (B) |
| | polymer | Content | 0.05 | 0.05 | 0.05 | 0.05 | 0.05 | 0.05 | 0.05 |
| | | (mass %) | | | | | | | |
| | Acidic | Type | succinic | malonic | malonic | — | phosphoric | hydrochloric | lactic |
| | compound | | acid | acid | acid | | acid | acid | acid |
| | | pKa | 5.6 | 5.7 | 5.7 | — | 7.2 | −7 | 3.7 |
| | Nonionic | Type | water- | — | — | — | — | — | — |
| | polymer | | soluble | | | | | | |
| | | | nylon | | | | | | |
| | | Content | 0.005 | — | — | — | — | — | — |
| | | (mass %) | | | | | | | |
| | pH | | 5.6 | 6 | 6 | 6 | 5.6 | 5.6 | 5.6 |
| | \|pKa-apH\| | | 0 | 0.3 | 0.3 | — | 1.6 | 12.6 | 1.9 |
| Results | Polishing | TEOS(Å/min) | 1759 | 1416 | 1619 | 404 | 1811 | 1122 | 1210 |
| | evaluation | SiN(Å/min) | 35 | 170 | 97 | 71 | 37 | 37 | 36 |
| | | TEOS/SiN | 50 | 8 | 17 | 6 | 49 | 30 | 34 |
| | | selective ratio | | | | | | | |

| | | | | | | | |
|---|---|---|---|---|---|---|---|
| pH change | 0.07 | 0.01 | 0.03 | 0.03 | 0.18 | 0.19 | 0.18 |

For the polishing agents in Examples 1 to 8, each of which contains abrasive grains, a specific anionic polymer, and a specific acidic compound, and satisfies |pKa−pH|≤1.5, it was shown that the removal rate of the silicon oxide film was high and the removal rate of the silicon nitride film was suppressed, so that a high selective ratio was obtained. Further, for the polishing agents in Examples 1 to 7, it was shown that the stability of pH and the viscosity was excellent, and stable performance could be maintained. Regarding the polishing agent in Examples 7 and 8, each of which also contained a nonionic polymer, the removal rate of the silicon oxide film was more improved than that of the polishing agent in Example 4. It is inferred that by combining a nonionic polymer, the wettability of the polishing agent for the surface to be polished was improved, so that the polishing agent came into contact with the abrasive grains more frequently, and as a result, the removal rate of the silicon oxide film was improved.

In contrast, in the polishing agents in Examples 9 to 10, for each of which an anionic polymer having a high acid value was used, it was shown that the removal rate of the silicon nitride film was not sufficiently suppressed, so that the selective ratio decreased. In the polishing agent in Example 11, which did not contain an acidic compound, the removal rate of the silicon oxide film decreased, so that the selective ratio was insufficient. Further, the polishing agents in Examples 12 to 14, of each of which |pKa−pH| was higher than 1.5, had a problem in the storage stability, and it was shown that it was difficult to maintain the performance of the polishing agent.

From the above-described matters, it became obvious that in the polishing agent according to this embodiment, it is possible to, while maintaining the removal rate of the silicon oxide film, suppress the removal rate of the stopper film; a high selective ratio was obtained; and the performance could be maintained for a long time

According to the present disclosure, for example, high-speed polishing can be carried out in CMP of a surface to be polished including an insulating film. Therefore, a polishing method according to the present disclosure is suitable for the polishing of an insulating film for STI in the manufacturing of semiconductor devices.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A polishing agent containing abrasive grains, an anionic polymer, an acidic compound selected from phosphoric acid compounds and organic acid compounds, and water, wherein
the anionic polymer is a copolymer containing a hydrophobic monomer and an anionic monomer,
an acid value of the anionic polymer is 20 mgKOH/g to 400 mgKOH/g,
a partition coefficient (log D) of the hydrophobic monomer is 0 to 4,
the anionic monomer contains at least one type selected from unsaturated monocarboxylic acids and salts thereof, and
when an acid compound having a highest molar concentration among the acidic compounds is defined as a first acidic compound, pKa of the first acidic compound and pH of the polishing agent satisfy a relationship expressed by below-shown Formula (1)
$$\vert pKa - pH \vert \leq 1.5 \qquad ( 1 )$$
where when the first acidic compound has two or more acid dissociation constants, pKa represents an acid dissociation constant closest to pH.

2. The polishing agent according to claim 1, wherein the abrasive grains include at least one type selected from the group consisting of silica particles, alumina particles, zirconia particles, cerium compound particles, titania particles, germania particles, composite particles thereof, and core shell-type particles.

3. The polishing agent according to claim 2, wherein the abrasive grains include cerium compound particles.

4. The polishing agent according to claim 2, wherein the abrasive grains include ceria particles.

5. The polishing agent according to claim 1, wherein a content of the abrasive grains is 0.01 to 10.0 wt. % based on a total weight of the polishing agent.

6. The polishing agent according to claim 1, wherein an acid value of the anionic polymer is 20 mgKOH/g to 300 mgKOH/g.

7. The polishing agent according to claim 1, wherein a partition coefficient (log D) of the hydrophobic monomer is 0 to 3.

8. The polishing agent according to claim 1, wherein the hydrophobic monomer contains alkyl (meth)acrylate.

9. The polishing agent according to claim 1, wherein a weight-average molecular weight of the anionic polymer is 1,000 to 100,000.

10. The polishing agent according to claim 1, wherein a ratio of the hydrophobic monomer in the anionic polymer is 10 to 95 mol % based on whole monomers constituting the anionic polymer.

11. The polishing agent according to claim 1, wherein a content of the anionic polymer is 0.02 wt. % to 0.5 wt. % based on a total weight of the polishing agent.

12. The polishing agent according to claim 1, wherein the pKa is 4 to 9.

13. The polishing agent according to claim 1, further containing a nonionic polymer.

14. The polishing agent according to claim 1, wherein pH is 4 to 9.

15. A polishing method in which a polishing pad is brought into contact with a surface to be polished of a semiconductor substrate while supplying a polishing agent therebetween, and the surface to be polished is polished by relative motion of the surface to be polished and the polishing pad, wherein the polishing agent is a polishing agent according to claim 1.

16. A method for manufacturing a semiconductor component, wherein the semiconductor component is obtained by dividing a semiconductor substrate having a surface to be polished, polished by the polishing method according to claim 15 into pieces.

17. An additive solution for a polishing agent containing an anionic polymer, an acidic compound selected from phosphoric acid compounds and organic acid compounds, and water, wherein
the anionic polymer is a copolymer containing a hydrophobic monomer and an anionic monomer,
an acid value of the anionic polymer is 20 mgKOH/g to 400 mgKOH/g,
a partition coefficient (log D) of the hydrophobic monomer is 0 to 4,
the anionic monomer contains at least one type selected from unsaturated monocarboxylic acids and salts thereof, and
when an acid compound having a highest molar concentration among the acidic compounds is defined as a first acidic compound, pKa of the first acidic compound and pH of the additive solution for the polishing agent satisfy a relationship expressed by below-shown Formula (1)
$$\vert pKa - pH \vert \leq 1.5 \qquad ( 1 )$$
where when the first acidic compound has two or more acid dissociation constants, pKa represents an acid dissociation constant closest to pH.
